(19) United States
(12) Patent Application Publication
(10) Pub. No.: US 2026/0165056 A1
(43) Pub. Date: Jun. 11, 2026

(54) SUBSTRATE PROCESSING APPARATUS AND SUBSTRATE PROCESSING METHOD

(71) Applicant: SEMES CO., LTD., Cheonan-si (KR)

(72) Inventors: Jun Hee CHOI, Yongin-si (KR); Ki Hoon CHOI, Cheonan -si (KR); Tae Keun KIM, Siheung-si (KR); Kang Sul KIM, Hwaseong-si (KR); Kyeong Min LEE, Hwaseong-si (KR); Yong Jun KIM, Suwon-si (KR)

(73) Assignee: SEMES CO., LTD., Cheonan-si (KR)

(21) Appl. No.: 19/409,218

(22) Filed: Dec. 4, 2025

(30) Foreign Application Priority Data
Dec. 9, 2024 (KR) 10-2024-0181805

(51) Int. Cl. H10P 50/64; H10P 72/00

(52) U.S. Cl. CPC H10P 50/642; H10P 72/0424

(57) ABSTRACT

Disclosed is a method of processing a substrate. The method includes: a first etching operation of rotating a substrate having a first film and a second film and etching the second film by supplying an etchant to the substrate; and after the first etching operation, a second etching operation of etching the second film by supplying the etchant to the rotating substrate, in which a second temperature, which is a temperature for etching the second film in the second etching operation, is lower than a first temperature for etching the second film in the first etching operation.

### CROSS-REFERENCE TO RELATED APPLICATION

This application claims priority to and the benefit of Korean Patent Application No. 10-2024-0181805 filed in the Korean Intellectual Property Office on Dec. 9, 2024, the entire contents of which are incorporated herein by reference.

### TECHNICAL FIELD

The present invention relates to a substrate processing method and a substrate processing apparatus, and more specifically, to a substrate processing method and a substrate processing apparatus that process a substrate by adjusting a temperature of an etchant.

### BACKGROUND ART

The semiconductor process includes a wet process of supplying a treatment solution onto a substrate so that the substrate and the treatment solution react physically and chemically. This process is performed by placing the substrate on a spin chuck so that a pattern surface faces up or down, supplying the treatment solution onto the substrate in a state in which the spin chuck is rotated, and then drying a wafer.

In general, since the temperature of the treatment solution affects the characteristics of processing the substrate, the treatment solution is supplied at a constant temperature during the process of processing the substrate by supplying the treatment solution. Accordingly, when the treatment solution is an etchant, the etching rate and selectivity are kept constant during the etching process. However, as the etching process proceeds, the required etching rate and selectivity may change. For example, a relatively high etching rate is required in an initial operation of etching, but a high selectivity may be required in a later operation of etching. However, since it is difficult to adjust the temperature of the supplied etchant, it is difficult to select the etching rate and selectivity by changing the temperature of the etchant during the process.

### SUMMARY OF THE INVENTION

The present invention has been made in an effort to provide a substrate processing apparatus and a substrate processing method capable of providing different temperatures of an etchant supplied to a substrate.

The present invention has also been made in an effort to provide a substrate processing apparatus and a substrate processing method capable of adjusting an etching rate during an etching process.

The present invention has also been made in an effort to provide a substrate processing apparatus and a substrate processing method capable of adjusting a selectivity during an etching process.

The objectives of the present disclosure are not limited thereto and other objectives not stated herein may be clearly understood by those skilled in the art from the following description.

An exemplary embodiment of the present disclosure, a method of processing a substrate, the method comprising: a first etching operation of rotating a substrate having a first film and a second film and etching the second film by supplying an etchant to the substrate; and after the first etching operation, a second etching operation of etching the second film by supplying the etchant to the rotating substrate, wherein a second temperature, which is a temperature for etching the second film in the second etching operation, may be lower than a first temperature for etching the second film in the first etching operation.

According to the exemplary embodiment of the present invention, wherein the etchant may be provided such that an etching selectivity of the second film with respect to the first film in the second etching operation is higher than an etching selectivity of the second film with respect to the first film in the first etching operation.

According to the exemplary embodiment of the present invention, wherein the first etching operation and the second etching operation are continuously may performed.

According to the exemplary embodiment of the present invention, wherein the etchant may be supplied to the substrate at the first temperature in the first etching operation through a nozzle and supplied to the substrate at the second temperature in the second etching operation.

According to the exemplary embodiment of the present invention, wherein the nozzle includes: a first nozzle; and a second nozzle different from the first nozzle, and the etchant is supplied from the first nozzle to the substrate at the first temperature during the first etching operation, and may be supplied from the second nozzle to the substrate at the second temperature during the second etching operation.

According to the exemplary embodiment of the present invention, wherein the first temperature is room temperature or higher, and the second temperature may be room temperature or lower.

According to the exemplary embodiment of the present invention, wherein the first temperature is 20° C. to 40° C., and the second temperature may be 10° C. to 30° C.

According to the exemplary embodiment of the present invention, wherein in the first etching operation and the second etching operation, the etchant is supplied to the substrate at the first temperature, and the etchant supplied in the second etching operation may be temperature-adjusted to the second temperature.

According to the exemplary embodiment of the present invention, wherein the temperature of the substrate may be different in the first etching operation and the second etching operation.

According to the exemplary embodiment of the present invention, wherein in the second etching operation, a fluid of a third temperature may be discharged toward a rear surface of the substrate, and the third temperature may be lower than the second temperature.

According to the exemplary embodiment of the present invention, wherein the first film is a SiGe film, and the second film may be a SiGe film with a Ge content higher than a Ge content of the first film.

According to the exemplary embodiment of the present invention, wherein the first film and the second film may be stacked on each other.

According to the exemplary embodiment of the present invention, wherein the substrate further may includes an Si film stacked with the first film and the second film.

An exemplary embodiment of the present disclosure, an apparatus for processing a substrate, the apparatus comprising: a housing providing an inner space; a cup body disposed in the inner space and providing a processing space for processing the substrate; a support unit configured to support and rotate a substrate including a first film and a second film in the processing space; an etchant supply unit configured to supply an etchant for etching any one of the plurality of films onto the substrate supported by the support unit; and a controller, the controller controls the support unit and the etchant supply unit to perform: a first etching operation of rotating the substrate and etching the second film by supplying an etchant to the substrate; and a second etching operation of etching the second film by supplying the etchant to the rotating substrate, after the first etching operation, and a second temperature, which is a temperature for etching the second film in the second etching operation, may be lower than a first temperature for etching the second film in the first etching operation.

According to the exemplary embodiment of the present invention, wherein the etchant supply unit includes: a first nozzle; and a second nozzle different from the first nozzle, and the first nozzle supplies the etchant of the first temperature to the substrate in the first etching operation, and the second nozzle may supplies the etchant of the second temperature to the substrate in the second etching operation.

According to the exemplary embodiment of the present invention, wherein the etchant supply unit includes a nozzle for discharging the etchant, the support unit includes: a spin chuck on which the substrate is placed; and a rear nozzle for discharging a fluid toward a rear surface of the substrate supported by the spin chuck, the controller discharges the etchant of the first temperature through the nozzle during the first etching operation and the second etching operation, and discharges the fluid of a third temperature through the rear nozzle in the second etching operation, and the third temperature may be lower than the second temperature.

According to the exemplary embodiment of the present invention, wherein the first film and the second film are provided to be stacked on each other, the substrate further includes an Si film stacked with the first film and the second film, and the first film is a SiGe film, and the second film may be a SiGe film with a Ge content higher than a Ge content of the first film.

An exemplary embodiment of the present disclosure, a method of processing a substrate, in which a second SiGe film is selectively etched on a substrate having a Si film, a first SiGe film, and the second SiGe film having a higher Ge content than the first SiGe film which are stacked on each other, the method may comprising: a first etching operation of etching the second SiGe film by supplying an etchant of a first temperature to the rotating substrate; and after the first etching operation, a second etching operation of etching the second SiGe film at an etching selectivity higher than an etching selectivity of the first etching operation by supplying an etchant of a second temperature which is lower than the first temperature.

According to the exemplary embodiment of the present invention, wherein the first etching operation and the second etching operation are continuously performed, and the etchant may be supplied to the substrate at the first temperature in the first etching operation through a nozzle and supplied to the substrate at the second temperature in the second etching operation.

According to the exemplary embodiment of the present invention, wherein the first temperature is 20° C. to 40° C., and the second temperature may be 10° C. to 30° C.

According to the exemplary embodiment of the present invention, it is possible to provide different temperatures of an etchant supplied to a substrate.

Further, according to the exemplary embodiment of the present invention, it is possible to adjust an etching rate during an etching process.

Further, according to the exemplary embodiment of the present invention, it is possible to adjust a selectivity during an etching process.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a top plan view schematically illustrating a substrate processing apparatus according to an exemplary embodiment of the present invention.

FIG. 2 is a diagram schematically illustrating a state of a substrate to be processed according to an exemplary embodiment of the present invention.

FIG. 3 is a diagram schematically illustrating an exemplary embodiment of a liquid treating chamber of FIG. 1.

FIG. 4 is a diagram illustrating an exemplary embodiment of an etchant supply unit of FIG. 3.

FIG. 5 is a diagram illustrating another exemplary embodiment of the etchant supply unit of FIG. 3.

FIG. 6 is a flowchart illustrating a substrate processing method according to an exemplary embodiment of the present invention.

FIG. 7 is a diagram schematically illustrating an exemplary embodiment of a first etching operation of FIG. 6.

FIG. 8 is a diagram schematically illustrating an exemplary embodiment of a second etching operation of FIG. 6.

FIG. 9 is a diagram sequentially illustrating a substrate processed by the substrate processing method according to the exemplary embodiment of the present invention.

FIG. 10 is a diagram schematically illustrating still another exemplary embodiment of the liquid treating chamber of FIG. 1.

FIG. 11 is a diagram schematically illustrating a state of processing the substrate through the liquid treating chamber of FIG. 10.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as an object to be treated. However, the technical idea of the present invention may be applied to devices used for treating other types of substrates other than wafers as objects to be treated.

Hereinafter, an exemplary embodiment of the present invention will be described with reference to the accompanying drawings.

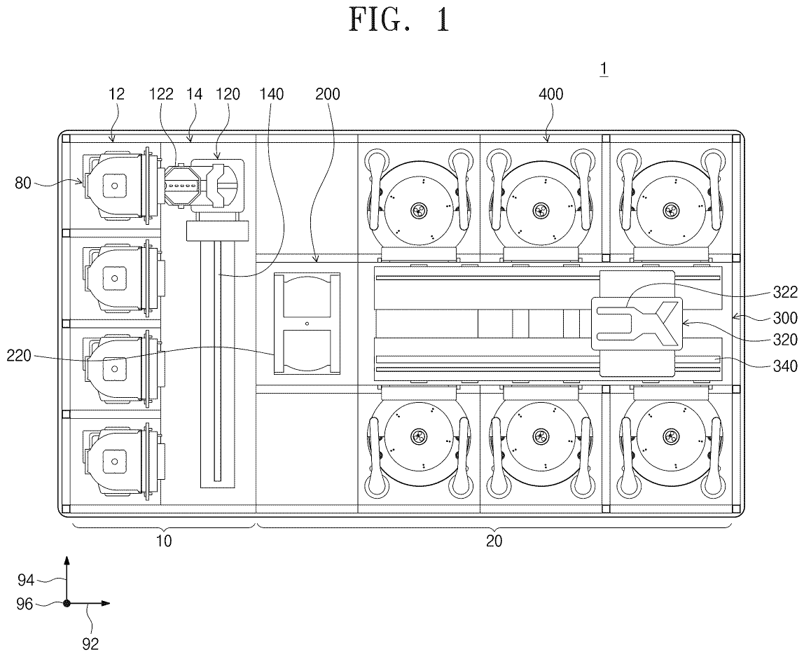

FIG. 1 is a top plan view schematically illustrating a substrate processing apparatus according to an exemplary embodiment of the present invention. Referring to FIG. 1, a substrate processing apparatus includes an index module 10, a treating module 20, and a controller 30. According to the exemplary embodiment, the index module 10 and the treating module 20 are disposed along one direction. Hereinafter, the direction in which the index module 10 and the treating module 20 are disposed is referred to as a first direction 92, and when viewed from above, a direction perpendicular to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80.

A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal direction is the second direction 94 is provided within the index frame 14, and the index robot 120 may be provided to be movable on the guide rail 140. The index robot 120 includes a hand 122 on which the substrate W is placed, and the hand 122 may be provided to be movable forward and backward, rotatable about the third direction 96, and movable along the third direction 96. The plurality of hands 122 is provided while being spaced apart from each other in the up and down direction, and is capable of independently moving forward and backward.

The treating module 20 includes a buffer unit 200, a transfer chamber 300, and a treating chamber 400. The buffer unit 200 provides a space in which the substrate W loaded into the treating module 20 and the substrate W unloaded from the treating module 20 stay temporarily. The treating chamber 400 performs a processing process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction is the first direction 92. The buffer unit 200 may be disposed between the index module 10 and the transfer chamber 300. A plurality of liquid treating chambers 400 is provided and may be disposed on the side of the transfer chamber 300. The liquid treating chamber 400 and the transfer chamber 300 may be disposed in the second direction 94. The buffer unit 200 may be located at one end of the transfer chamber 300.

According to the example, the liquid treating chambers 400 are respectively disposed on opposite sides of the transfer chamber 300. At each of opposite sides of the transfer chamber 300, the liquid treating chambers 400 may be provided in an array of A×B (each of A and B is 1 or a natural number greater than 1) in the first direction 92 and the third direction 96.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

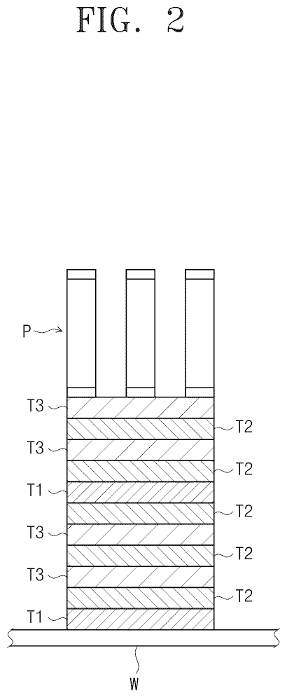

FIG. 2 is a diagram schematically illustrating a state of a substrate to be processed according to an exemplary embodiment of the present invention. Referring to FIG. 2, a substrate W to be processed may be provided as a substrate W on which a first film T1, a second film T2, and a third film T3 are formed. The first film T1 and the second film T2 may be silicon germanium (SiGe) films. Also, Ge contents of the first film T1 and the second film T2 may be different from each other. The Ge content of the first film T1 may be higher than that of the second film T2. For example, the Ge content of the first film T1 may be 40 to 50%, and the Ge content of the second film T2 may be 15 to 30%. The third film T3 may be a silicon (Si) film. Each of the first film T1, the second film T2, and the third film T3 may be provided in plural and provided in a stacked structure. The numbers of the first film T1, the second film T2, and the third film T3 may be different from each other. Also, a pattern P may be provided in an upper portion of the stacked structure. The pattern P may have a structure in which a plurality of materials is stacked. For example, the pattern P may include a silicon nitride (SiN) layer, a polycrystalline silicon (poly-Si) layer, and a silicon oxide film (SiO) layer.

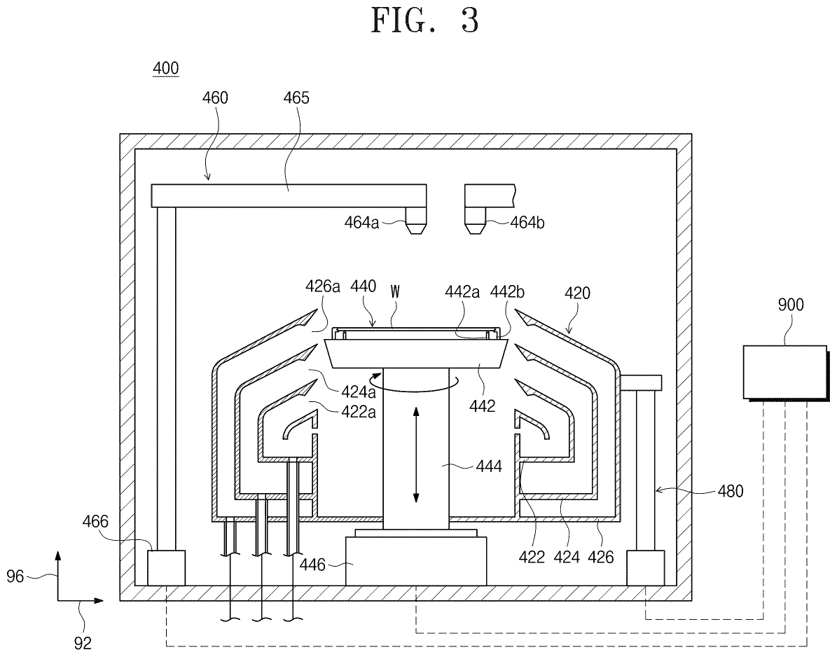

FIG. 3 is a diagram schematically illustrating the liquid treating chamber 400 of FIG. 1 according to the exemplary embodiment. Referring to FIG. 3, the liquid treating chamber 400 includes a housing 410, a cup 420, a support unit 440, an etchant supply unit 460, a lifting unit 480, and a controller 900.

The housing 410 is provided in a generally rectangular parallelepiped shape. The cup 420, the support unit 440, and the etchant supply unit 460 are disposed within the housing 410.

The cup 420 has a treatment space with an open top, and the substrate W is liquid-treated in the treatment space. The support unit 440 supports the substrate W in the treatment space. The etchant supply unit 460 supplies the liquid to the substrate W supported by the support unit 440. The liquid may be provided in a plurality of types, and may be sequentially supplied onto the substrate W. The lifting unit 480 adjusts a relative height between the cup 420 and the support unit 440.

According to an example, the cup 420 includes a plurality of recovery containers 422, 424, and 426. Each of the recovery containers 422, 424, and 426 has a recovery space of recovering the liquid used for the processing of the substrate. Each of the recovery containers 422, 424, and 426 is provided in a ring shape surrounding the support unit 440. As the liquid treatment process proceeds, the treatment solution scattered by the rotation of the substrate W is introduced into the recovery space through the inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 includes a spin chuck 442 and a drive shaft 444. The upper surface of the spin chuck 442 is provided in a generally circular shape, and may have a diameter larger than that of the substrate W. Further, a support pin 442a supporting the rear surface of the substrate W is provided at the center of the support plate 442, and the upper end of the support pin 442a is provided to protrude from the support plate 442 so that the substrate W is spaced apart from the support plate 442 by a predetermined distance. A chuck pin 442b is provided at an edge of the spin chuck 442. The chuck pin 442b is provided to protrude upward from the support plate 442, and supports a side portion of the substrate W so that the substrate W is not separated from the support unit 440 when the substrate W is rotated. The drive shaft 444 is driven by the driver 446, is connected to the center of the rear surface of the substrate W, and rotates the spin chuck 442 about its central axis.

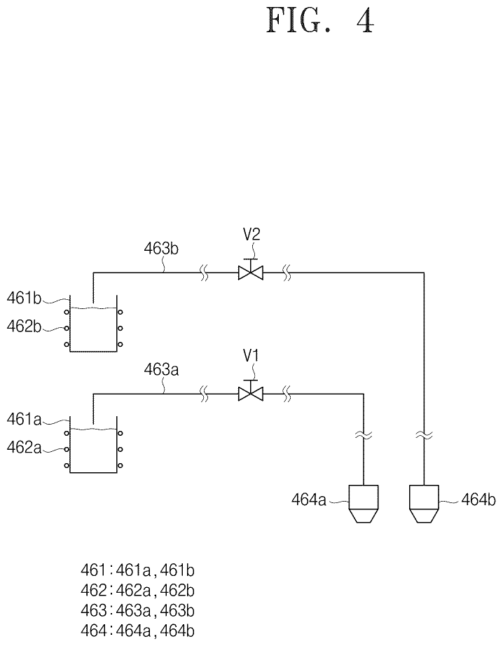

The etchant supply unit 460 supplies the etchant onto the substrate W supported by the support unit 440. FIG. 4 is a diagram illustrating an exemplary embodiment of the etchant supply unit of FIG. 3. Referring to FIG. 4, the etchant supply unit 460 has an etchant supply source 461, a temperature adjusting unit 462, an etchant supply line 463, a nozzle 464, an arm 465, and a driver 466.

The etchant supply source 461 may store and supply an etchant. The etchant supply source 461 may include a first etchant supply source 461a and a second etchant supply source 461b. The first etchant supply source 461a may store and supply the etchant of a first temperature. The second etchant supply source 461b may store and supply the etchant of a second temperature.

The temperature adjusting unit 462 may include a heater 464a and a chiller 464b. The heater 464a may be installed on the first etchant supply source 461a to heat the etchant to the first temperature. Furthermore, the chiller 464b may be installed on the second etchant supply source 461b to cool the etchant to the second temperature. For example, the first temperature may be higher than the second temperature, and the first temperature may be 20 [symbol] to 40 [symbol] , and the second temperature may be 10 [symbol] to 30 [symbol] .

The etchant supply line 463 connects the nozzle 464 to the etchant supply source 461. The etchant supply line 463 may include a first etchant supply line 463a and a second etchant supply line 463b. The first etchant supply line 463a connects the first nozzle 464a and the first etchant supply source 461a. The second etchant supply line 463b connects the second nozzle 464b and the second etchant supply source 461b.

The nozzle 464 may include a first nozzle 464a and a second nozzle 464b. The first nozzle 464a may discharge the etchant of the first temperature. The second nozzle 464b may discharge the etchant of the second temperature. The first nozzle 464a and/or the second nozzle 464b may be provided to discharge the etchant vertically or obliquely toward the substrate W.

Referring back to FIG. 3, the first nozzle 464a and the second nozzle 464b may be supported by the arm 465, and the arm 465 may be driven by the driver 466. The driver 466 moves the positions of the first nozzle 464a and the second nozzle 464b. Accordingly, the positions of the first nozzle 464a and the second nozzle 464b may be changed.

The treatment solution supply unit 460 may optionally further include one or more nozzles in addition to the first nozzle 461 and the second nozzle 462. The added nozzle may supply another type of treatment solution to the substrate. For example, the different types of treatment solution may be a drying solution for drying the substrate W. For example, the drying solution may be isopropyl alcohol.

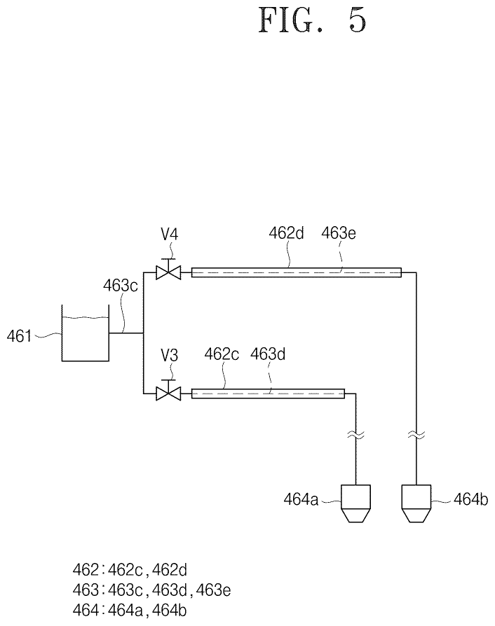

FIG. 5 is a diagram illustrating another exemplary embodiment of the etchant supply unit of FIG. 3. Hereinafter, descriptions of portions overlapping the portions described with reference to FIG. 4 will be omitted and descriptions will be made by quoting reference numerals as they are.

The etchant supply line 463 includes a main line 463c, a first supply line 463d, and a second supply line 463e. One end of the main line 463a is connected to the etchant supply source 461. The other end of the main line 463c branches to the first supply line 463d and the second supply line 463e. The first supply line 463d connects the main line 463c to the first nozzle 464a. The second supply line 463d connects the main line 463c to the second nozzle 464b.

The temperature adjusting unit 462 may include an in-line heater 462c and an in-line chiller 462d. The in-line heater 462c is installed on the first supply line 463d. The in-line heater 462c is installed to surround the first supply line 463d. Accordingly, the in-line heater 462c may heat the etchant flowing through the first supply line 463d. According to an example, the in-line heater 462c may heat the etchant to the first temperature. The in-line chiller 462d is installed on the second supply line 463e. The in-line chiller 462d is installed to surround the second supply line 463e. Accordingly, the in-line chiller 462d may cool the etchant flowing through the second supply line 463e. According to an example, the in-line chiller 462d may cool the etchant to the second temperature.

The lifting unit 480 moves the cup 420 in the up and down direction. By the up and down movement of the cup 420, a relative height between the cup 420 and the substrate W is changed. Accordingly, the recovery containers 422, 424, and 426 for recovering the treatment solution are changed according to the type of liquid supplied to the substrate W, and thus the liquids may be separated and recovered. Unlike the description, the cup 420 may be fixedly installed, and the lifting unit 480 may move the support unit 440 in the vertical direction.

Each of the configurations of the substrate processing apparatus described above may be controlled by the controller 900. The controller 900 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

Hereinafter, a method of processing a substrate will be described. The substrate processing method described below may be performed by the substrate processing apparatus described with reference to FIGS. 1 to 5. Accordingly, hereinafter, a substrate processing method according to an exemplary embodiment will be described by referring to reference numerals illustrated in FIGS. 1 to 5. In addition, the substrate processing method described below may be performed by controlling, by the controller 900, components included in the substrate processing apparatus described above.

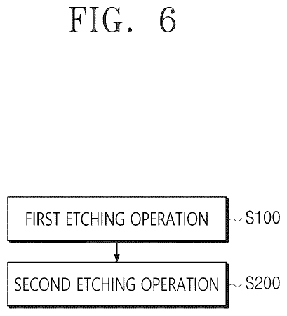

FIG. 6 is a flowchart illustrating a substrate processing method according to an exemplary embodiment of the present invention. Referring to FIG. 6, the substrate processing method may include a first etching operation S100 and a second etching operation S200.

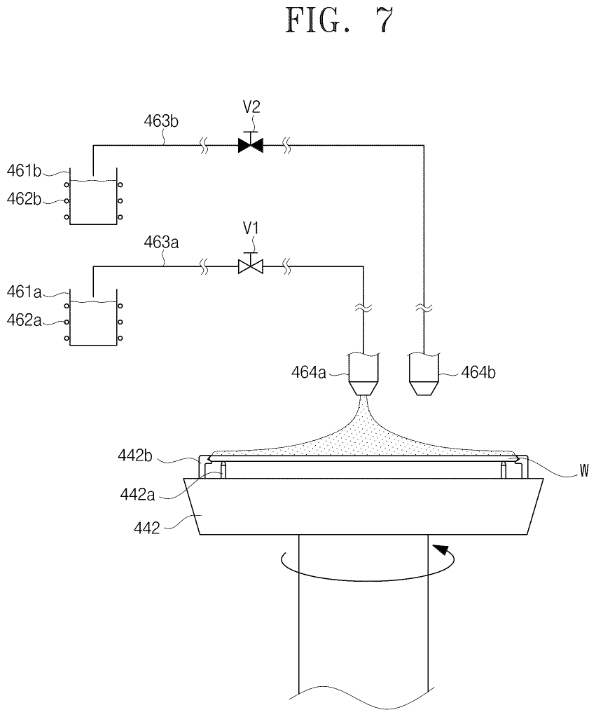

FIG. 7 is a diagram schematically illustrating an exemplary embodiment of a first etching operation of FIG. 6. Referring to FIG. 7, the first etching operation S100 is an operation of processing the substrate W with an etchant at a first temperature. According to an example, in the first etching operation S100, the substrate W is rotated and the etchant of a first temperature is discharged onto the substrate W from the first nozzle 464a. According to the exemplary embodiment of the present invention, the etchant may be heated to the first temperature by the heater 463a or the in-line heater 463c. However, the present invention is not limited thereto, and the etchant may be heated to a temperature higher than the first temperature in consideration of a decrease in temperature of the etchant. According to an example, the etchant may be heated to a temperature higher than about 10° C. than the first temperature. The etchant may have a high etching rate with respect to the first film T1 at the first temperature. Accordingly, a time taken to process the substrate W may be shortened.

After the first etching operation S100, a second etching operation S200 is performed. The first etching operation S100 and the second etching operation S200 may be continuously performed. The continuous performing may mean a state in which supply of the etchant supplied onto the substrate W is not stopped. According to an example, in the case where the first nozzle 464a and the second nozzle 464b vertically discharge the etchant toward the substrate W, when the first etching operation S100 is terminated, the first nozzle 464a is withdrawn, and while the second nozzle 464b moves toward the center of the substrate W, the first nozzle 464a and the second nozzle 464b discharge the etchant to perform the first etching operation S100 and the second etching operation S200. According to another exemplary embodiment, when the first nozzle 464a or the second nozzle 464b discharge the etchant vertically or obliquely toward the substrate W, the supply of the etchant from the first nozzle 464a is stopped and at the same time, the etchant is supplied from the second nozzle 464b, so that the first etching operation S100 and the second etching operation S200 may be continuously performed.

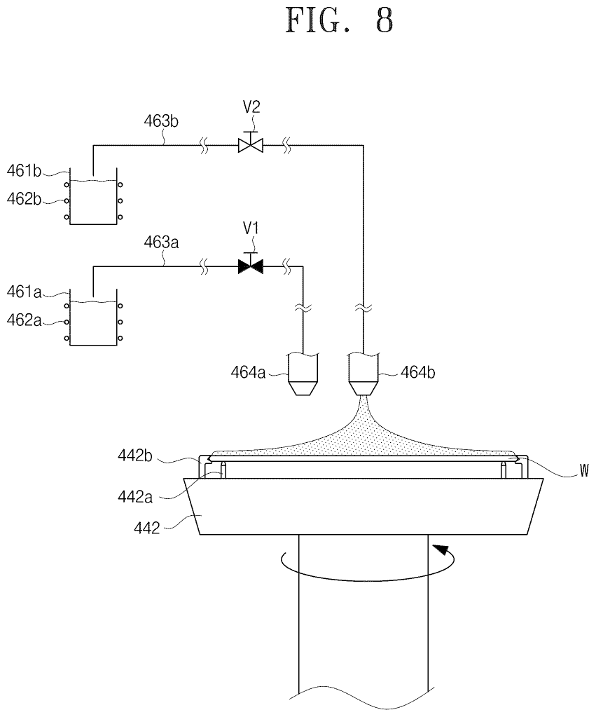

FIG. 8 is a diagram schematically illustrating an exemplary embodiment of the second etching operation of FIG. 6. Referring to FIG. 8, the second etching operation S200 is an operation of processing the substrate W with an etchant at a second temperature. According to an example, in the second etching operation S200, the substrate W is rotated and the etchant of the second temperature is discharged onto the substrate W from the second nozzle 464b. According to an exemplary embodiment of the present invention, the etchant may be cooled to the second temperature by the chiller 463b or the in-line chiller 463d. However, the present invention is not limited thereto, and may be cooled to a temperature lower than the second temperature in consideration of an increase in the temperature of the etchant. According to an example, the etchant may be cooled to a temperature lower than about 10° C. than the second temperature. At the second temperature, the etchant may have a higher selectivity with respect to the first film T1 than the second film T2 and the third film T3. Accordingly, process accuracy in etching may be improved.

In general, during a wet process, the temperature of the treatment solution affects the processing speed. When the treatment solution is provided as an etchant, the temperature of the etchant affects not only the etching rate but also the selectivity. As the temperature of the etchant is higher, the etching rate is more improved, but the selectivity decreases, and as the temperature of the etchant is lower, the selectivity is more improved, but the etching rate decreases.

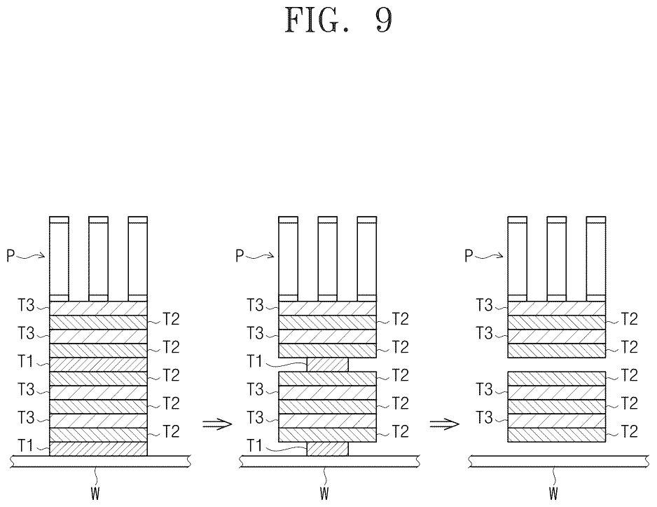

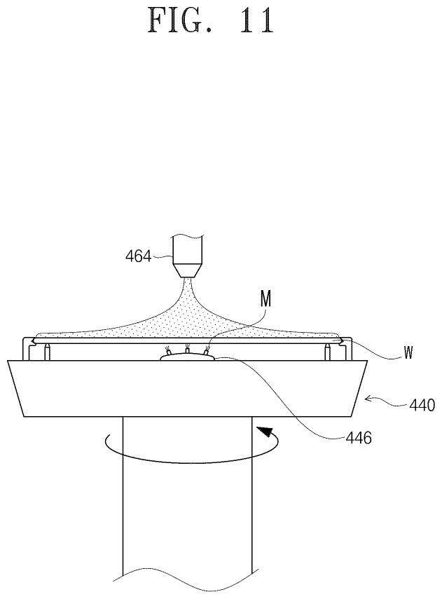

FIG. 9 is a diagram sequentially illustrating a substrate processed by the substrate processing method according to the exemplary embodiment of the present invention. Hereinafter, the present invention will be described based on the case where the etching treatment of the first film T1 with the etchant will be described as an example with reference to FIG. 11. Referring to FIG. 9, in the initial etching process, the difference in the areas in which the first film T1, the second film T2, and the third film T3 are exposed to the etchant is not large. In this case, the processing time may be shortened by increasing the etching rate by supplying the etchant at a high temperature. However, as the etching process gradually proceeds, the rate in which the second film T2 is exposed to the treatment solution increases. Since the possibility of etching the second film T2 increases as the area in which the second film T2 is exposed to the etchant increases, the selectivity needs to be improved to selectively etch only the first film T1. To this end, it is necessary to process the substrate W at low temperatures.

According to the exemplary embodiment of the present invention, by supplying the etchant of the first temperature in the first etching operation S100 and by supplying the etchant of the second temperature in the second etching operation S200, a high etching rate may be ensured in the initial etching process, and a high selectivity may be ensured as the etching process proceeds. Accordingly, it is possible to shorten the time required for the etching process and achieve the accuracy of the etching.

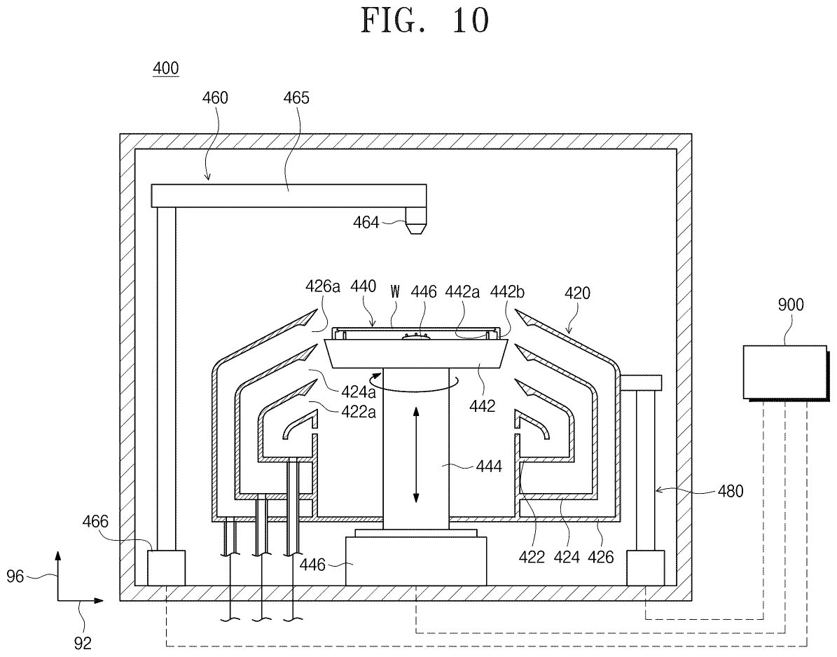

In the above example, the present invention has been described based on the case where the nozzle 464 includes the first nozzle 464a and the second nozzle 464b as an example. However, the present invention is not limited thereto, and only the nozzle 464 may be provided. FIG. 10 is a diagram schematically illustrating still another exemplary embodiment of the liquid treating chamber of FIG. 1, and FIG. 11 is a diagram schematically illustrating a state of processing the substrate through the liquid treating chamber of FIG. 10. Hereinafter, descriptions of parts overlapping the parts described with reference to FIGS. 1 to 8 will be omitted and described by referring to reference numerals used in FIGS. 1 to 8. Referring to FIGS. 10 and 11, the support unit 440 may further include a rear nozzle 446. A through hole in which the rear nozzle 446 is installed is formed at the center of the spin chuck 442, and the rear nozzle 446 may be installed on the upper surface of the spin chuck 442 along the through hole.

The rear nozzle 446 is provided to inject a fluid toward the rear surface of the substrate W. The rear nozzle 446 may discharge a fluid toward the center of the rear surface of the substrate W. The fluid may be a liquid. Also, the fluid may be provided at a third temperature. According to an example, the fluid may be deionized water (DIW), and the third temperature may be a temperature lower than the second temperature. Also, the third temperature may be a temperature capable of cooling the etchant of the first temperature to the second temperature.

According to another exemplary embodiment of the present invention, the nozzle 464 discharges the etchant of the first temperature onto the substrate W in the first etching operation S100 and the second etching operation S200, and additionally discharges the fluid from the rear nozzle 446. The substrate W may be cooled by the fluid, and the etchant supplied at the first temperature may be cooled to the second temperature. Accordingly, the substrate W may be processed with the etchant of the second temperature.

According to another exemplary embodiment of the present invention, the rear nozzle 446 may discharge a fluid during the first etching operation S100 and the second etching operation S200. When the temperature of the etchant is not provided at the first temperature and the second temperature, the fluid may be discharged to adjust the temperature of the substrate W, such that the substrate W may be processed at the first temperature and the second temperature. To this end, the fluid may be supplied to the rear nozzle 446 in a state in which the temperature is controlled by a means which is not illustrated. According to an example, the fluid may be heated to have a temperature higher than the first temperature in the first etching operation S100, and the fluid may be cooled to have a temperature lower than the second temperature in the second etching operation S200.

In addition, in the above-described example, the present invention has been described based on the case where the substrate W is processed with the etchant as an example. However, the present invention is not limited thereto, and other types of chemical solutions that process the substrate W may be provided instead of the etchant. At this time, the chemical solution may change its treatment characteristics according to temperature changes (e.g., formation of bubbles in the treatment solution, thermal stress applied to the substrate, and reduction of evaporation of the treatment solution).

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

What is claimed is:

1. A method of processing a substrate, the method comprising:
a first etching operation of rotating a substrate having a first film and a second film and etching the second film by supplying an etchant to the substrate; and
after the first etching operation, a second etching operation of etching the second film by supplying the etchant to the rotating substrate,
wherein a second temperature, which is a temperature for etching the second film in the second etching operation, is lower than a first temperature for etching the second film in the first etching operation.

2. The method of claim 1, wherein the etchant is provided such that an etching selectivity of the second film with respect to the first film in the second etching operation is higher than an etching selectivity of the second film with respect to the first film in the first etching operation.

3. The method of claim 1, wherein the first etching operation and the second etching operation are continuously performed.

4. The method of claim 3, wherein the etchant is supplied to the substrate at the first temperature in the first etching operation through a nozzle and supplied to the substrate at the second temperature in the second etching operation.

5. The method of claim 4, wherein the nozzle includes:
a first nozzle; and
a second nozzle different from the first nozzle, and
the etchant is supplied from the first nozzle to the substrate at the first temperature during the first etching operation, and is supplied from the second nozzle to the substrate at the second temperature during the second etching operation.

6. The method of claim 3, wherein the first temperature is room temperature or higher, and
the second temperature is room temperature or lower.

7. The method of claim 3, wherein the first temperature is 20° C. to 40° C., and the second temperature is 10° C. to 30° C.

8. The method of claim 3, wherein in the first etching operation and the second etching operation, the etchant is supplied to the substrate at the first temperature, and
the etchant supplied in the second etching operation is temperature-adjusted to the second temperature.

9. The method of claim 8, wherein the temperature of the substrate is different in the first etching operation and the second etching operation.

10. The method of claim 9, wherein in the second etching operation, a fluid of a third temperature is discharged toward a rear surface of the substrate, and
the third temperature is lower than the second temperature.

11. The method of claim 3, wherein the first film is a SiGe film, and the second film is a SiGe film with a Ge content higher than a Ge content of the first film.

12. The method of claim 11, wherein the first film and the second film are stacked on each other.

13. The method of claim 12, wherein the substrate further includes an Si film stacked with the first film and the second film.

14. An apparatus for processing a substrate, the apparatus comprising:
a housing providing an inner space;
a cup body disposed in the inner space and providing a processing space for processing the substrate;
a support unit configured to support and rotate a substrate including a first film and a second film in the processing space;
an etchant supply unit configured to supply an etchant for etching any one of the plurality of films onto the substrate supported by the support unit; and
a controller,
the controller controls the support unit and the etchant supply unit to perform:
a first etching operation of rotating the substrate and etching the second film by supplying an etchant to the substrate; and
a second etching operation of etching the second film by supplying the etchant to the rotating substrate, after the first etching operation, and
a second temperature, which is a temperature for etching the second film in the second etching operation, is lower than a first temperature for etching the second film in the first etching operation.

15. The apparatus of claim 14, wherein the etchant supply unit includes:
a first nozzle; and
a second nozzle different from the first nozzle, and
the first nozzle supplies the etchant of the first temperature to the substrate in the first etching operation, and
the second nozzle supplies the etchant of the second temperature to the substrate in the second etching operation.

16. The apparatus of claim 14, wherein the etchant supply unit includes a nozzle for discharging the etchant,
the support unit includes:
a spin chuck on which the substrate is placed; and
a rear nozzle for discharging a fluid toward a rear surface of the substrate supported by the spin chuck,
the controller discharges the etchant of the first temperature through the nozzle during the first etching operation and the second etching operation, and discharges the fluid of a third temperature through the rear nozzle in the second etching operation, and
the third temperature is lower than the second temperature.

17. The apparatus of claim 14, wherein the first film and the second film are provided to be stacked on each other,
the substrate further includes an Si film stacked with the first film and the second film, and
the first film is a SiGe film, and the second film is a SiGe film with a Ge content higher than a Ge content of the first film.

18. A method of processing a substrate, in which a second SiGe film is selectively etched on a substrate having a Si film, a first SiGe film, and the second SiGe film having a higher Ge content than the first SiGe film which are stacked on each other, the method comprising:
a first etching operation of etching the second SiGe film by supplying an etchant of a first temperature to the rotating substrate; and
after the first etching operation, a second etching operation of etching the second SiGe film at an etching selectivity higher than an etching selectivity of the first etching operation by supplying an etchant of a second temperature which is lower than the first temperature.

19. The method of claim 18, wherein the first etching operation and the second etching operation are continuously performed, and
the etchant is supplied to the substrate at the first temperature in the first etching operation through a nozzle and supplied to the substrate at the second temperature in the second etching operation.

20. The method of claim 19, wherein the first temperature is 20° C. to 40° C., and
the second temperature is 10° C. to 30° C.
